(19) United States
(12) Patent Application Publication
(10) Pub. No.: US 2024/0014083 A1
(43) Pub. Date: Jan. 11, 2024

(54) SEMICONDUCTOR DEVICE ASSEMBLIES WITH SCREEN-PRINTED EPOXY SPACERS AND METHODS FOR FORMING THE SAME

(71) Applicant: Micron Technology, Inc., Boise, ID (US)

(72) Inventors: Hem P. Takiar, Fremont, CA (US); Raj K. Bansal, Boise, ID (US); Jian Wei Lim, Singapore (SG); Li Wang, Singapore (SG); Jungbae Lee, Taichung (TW)

(21) Appl. No.: 18/217,827

(22) Filed: Jul. 3, 2023

Related U.S. Application Data
(60) Provisional application No. 63/358,434, filed on Jul. 5, 2022.
(60) Provisional application No. 63/358,438, filed on Jul. 5, 2022.

(51) Int. Cl. H01L 23/16; H01L 23/00; H01L 25/065; H01L 21/48

(52) U.S. Cl. CPC H01L 23/16; H01L 24/32; H01L 24/73; H01L 25/0657; H01L 24/48; H01L 21/4803; H01L 24/16; H01L 2224/73265; H01L 2224/48145; H01L 2224/32145; H01L 2224/32225; H01L 2224/16227; H01L 2924/182; H01L 2225/06562; H01L 2225/06506; H01L 2224/48227; H01L 2225/0651

(57) ABSTRACT

A method of making a semiconductor device assembly is provided. The method comprises attaching a first semiconductor device to an upper surface of a substrate and disposing a stencil over the upper surface of the substrate. The stencil includes (i) an opening and (ii) a cavity in which the first semiconductor device is disposed. The method further comprises screen-printing an epoxy material into the opening and onto the upper surface of the substrate, removing the stencil, and planarizing an upper surface of the epoxy material to form an epoxy spacer.

### CROSS-REFERENCE TO RELATED APPLICATIONS

The present application claims priority to U.S. Provisional Patent Application Nos. 63/358,434, filed Jul. 5, 2022, and 63/358,438, filed Jul. 5, 2022; each of which is incorporated herein by reference in its entirety.

### TECHNICAL FIELD

The present disclosure generally relates to semiconductor device assemblies, and more particularly relates to semiconductor device assemblies with screen-printed epoxy spacers and methods for forming the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic cross-sectional view of a semiconductor device assembly in accordance with embodiments of the present technology.

FIG. 2 is a simplified schematic cross-sectional view of a semiconductor device assembly in accordance with embodiments of the present technology.

FIGS. 3-9 are simplified schematic cross-sectional views illustrating a series of fabrication steps of semiconductor device assemblies in accordance with embodiments of the present technology.

FIG. 10 is a simplified schematic partial overhead view of a semiconductor device assembly in accordance with embodiments of the present technology.

FIG. 11 is a schematic view showing a system that includes a semiconductor device assembly configured in accordance with embodiments of the present technology.

FIG. 12 is a flow chart illustrating a method of making a semiconductor device assembly in accordance with embodiments of the present technology.

### DETAILED DESCRIPTION

Some semiconductor device assemblies include a heterogenous group of semiconductor devices, with different plan areas, thicknesses, connection methodologies, etc. To accommodate the packaging of these different devices into an assembly, it is sometimes beneficial to include spacers (e.g., structures which provide mechanical support to carry other devices, but which generally do not include circuitry). For example, to support a stack of semiconductor devices over a smaller device mounted directly to a package substrate, spacers taller than the smaller device can be provided on opposing sides thereof, so that the stack of larger devices can form a “bridge” over the smaller device. One approach to forming such spacers involves singulating chips from a bulk silicon die (i.e., with no active circuitry therein) and adhering them to the package substrate. Silicon spacers have the benefit of planarity, which is important in preventing structures stacked over the spacers from experiencing mechanical stresses. Various disadvantages of silicon spacers, however, include their significant contribution to the cost of an assembly, the possibility of contamination associated with debris caused by their singulation, and the constraints on their shape dictated by the method of singulating them (e.g., using a mechanical saw blade, only convex polygon shapes are possible).

To address these shortcomings and others, embodiments of the present technology provide epoxy spacers formed on package substrates by screen-printing. The planarity of a single epoxy spacer, and/or the co-planarity of multiple epoxy spacers, can be achieved by a pressing operation, and the accommodation of structures already present on the substrate before the screen-printing operation can be achieved through use of a three-dimensional stencil. The spacers can be readily formed in various complex (e.g., concave, irregular, etc.) polygonal and/or curved shapes adapted to the needs of various assembly configurations.

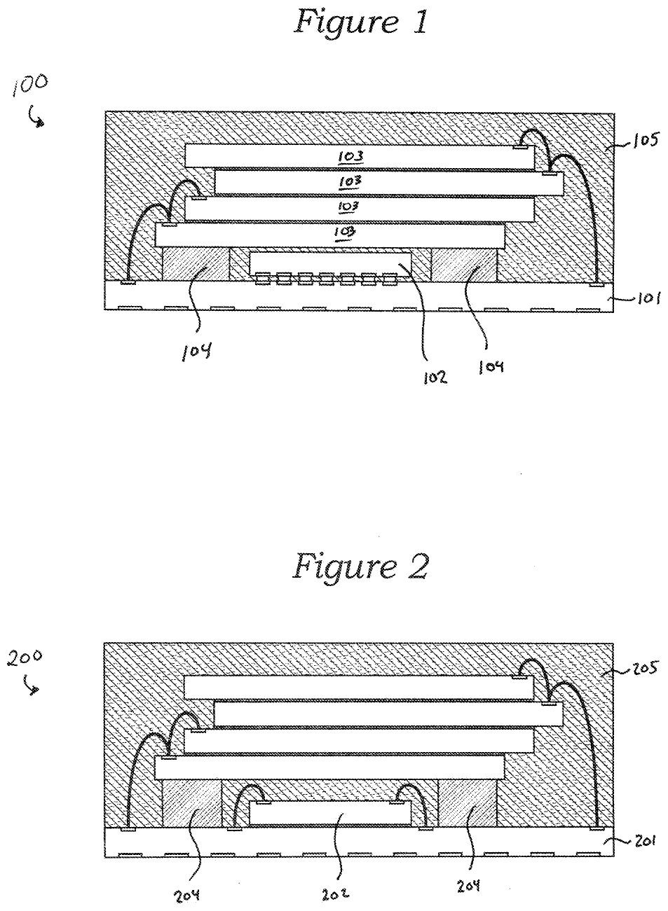

FIG. 1 is a simplified schematic cross-sectional view of a semiconductor device assembly 100 in accordance with embodiments of the present technology. As can be seen with reference to FIG. 1, assembly 100 can include a substrate 101 on which is mounted a first semiconductor die 102 (e.g., in a flip-chip arrangement in which a plurality of interconnects are formed between contacts of the substrate 101 and corresponding pads on the first semiconductor die 102). Assembly 100 can further include a stack of second semiconductor dies 103 (e.g., in a shingled-stack arrangement in which wire bonds connect pads of each second semiconductor die 103 to contacts of the substrate 101). The stack of second semiconductor dies 103, having a larger plan area than first semiconductor die 102 (e.g., as is commonly the case with a stack of memory dies over a controller die), are carried mechanically by epoxy spacers 104, disposed over the substrate 101 on either side of the first semiconductor die 102. The epoxy spacers 104 are configured to provide mechanical support for the stack of second semiconductor dies 103, and to allow them to “bridge” over the first semiconductor die 102.

Substrate 101 can further include exterior contact pads for providing external connectivity (e.g., via solder balls) to the first semiconductor die 102 and the second semiconductor dies 103 (e.g., power, ground, and I/O signals) through traces, lines, vias, and other electrical connection structures (not illustrated) in the substrate 101 that electrically connect the exterior contact pads to the semiconductor devices of the package. An underfill material (e.g., capillary underfill) can be provided between the first semiconductor die 102 and the substrate 101 to provide electrical insulation to the interconnects and the contacts. An encapsulant material 105 can at least partially encapsulate the stack of second semiconductor dies 103, the first semiconductor die 102, the epoxy spacers 104, and the substrate 101.

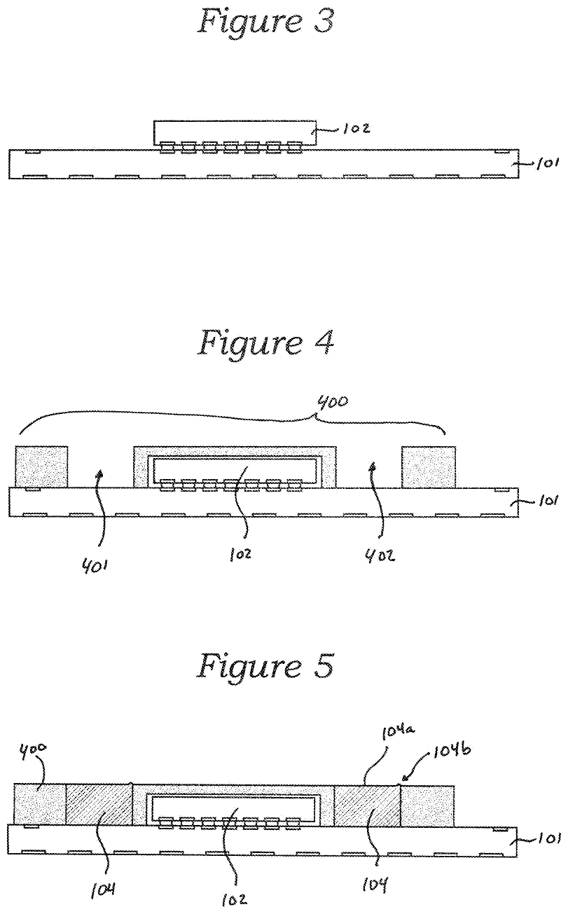

FIG. 2 is a simplified schematic cross-sectional view of a semiconductor device assembly 200 in accordance with embodiments of the present technology. As can be seen with reference to FIG. 2, assembly 200 can include a substrate 201 on which is mounted a first semiconductor die 202 (e.g., in a wire-bonded arrangement in which a plurality of wire bonds are formed between contacts of the substrate 201 and corresponding pads on the first semiconductor die 202). Assembly 200 can further include a stack of second semiconductor dies 203 (e.g., in a shingled-stack arrangement in which wire bonds connect pads of each second semiconductor die 203 to contacts of the substrate 201). The stack of second semiconductor dies 203, having a larger plan area than first semiconductor die 202 (e.g., as is commonly the case with a stack of memory dies over a controller die), are carried mechanically by epoxy spacers 204, disposed over the substrate 201 on either side of the first semiconductor die 202. The epoxy spacers 204 are configured to provide mechanical support for the stack of second semiconductor dies 203, and to allow them to “bridge” over the first semiconductor die 202 at a height sufficient to provide clearance for the wire bonds connecting the first semiconductor die 202 to the substrate 201.

Substrate 201 can further include exterior contact pads for providing external connectivity (e.g., via solder balls) to the first semiconductor die 202 and the second semiconductor dies 203 (e.g., power, ground, and I/O signals) through traces, lines, vias, and other electrical connection structures (not illustrated) in the substrate 201 that electrically connect the exterior contact pads to the semiconductor devices of the package. An underfill material (e.g., capillary underfill) can be provided between the first semiconductor die 202 and the substrate 201 to provide electrical insulation to the interconnects and the contacts. An encapsulant material 205 can at least partially encapsulate the stack of second semiconductor dies 203, the first semiconductor die 202, the epoxy spacers 204, and the substrate 201.

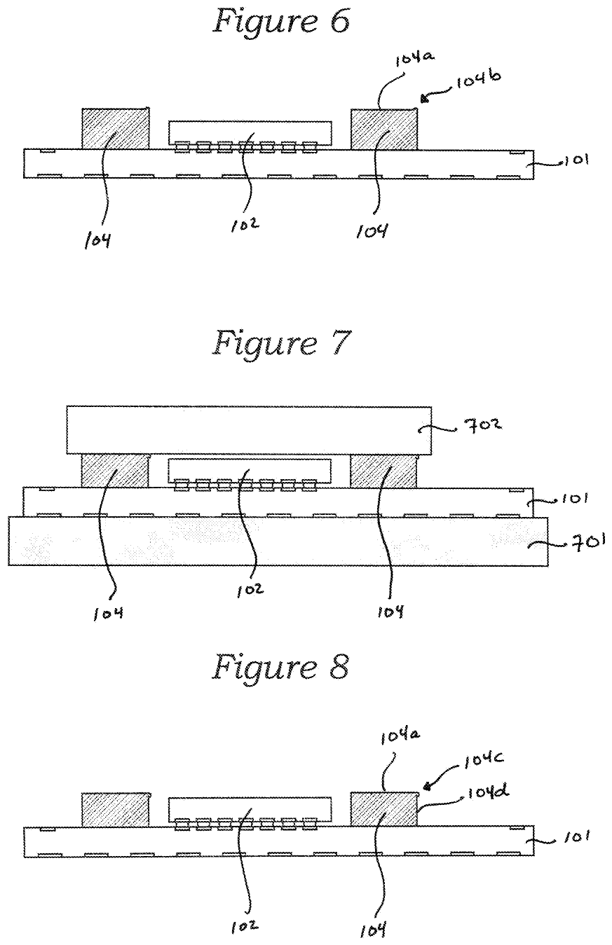

FIGS. 3-9 are simplified schematic cross-sectional views illustrating a series of fabrication steps of a semiconductor device assembly, such as assembly 100, in accordance with an embodiment of the present technology. Beginning with FIG. 3, a first semiconductor die 102 is coupled to a substrate 101 (e.g., in wafer-level, panel-level, strip-level, or in some embodiments, pre-singulated). Turning to FIG. 4, a three-dimensional screen-printing stencil 400 is positioned over the substrate 101 and over the first semiconductor die 102. The screen-printing stencil 400 is three-dimensional in that it includes one or more cavities facing the substrate 101 to accommodate structures already in-place, such as first semiconductor die 102. Screen-printing stencil 400 further includes one or more openings, such as openings 401 and 402, into which an epoxy material can be screen-printed. The results of such a screen-printing process are illustrated in FIG. 5, in which epoxy spacers 104 have been formed in the openings 401 and 402.

According to various aspects of the present disclosure, the material from which the epoxy spacers 104 are printed can be any one of a number of epoxy-based materials, such as epoxy mold compound (EMC) and/or B-stageable epoxy adhesive.

According to one aspect of the present disclosure, the screen-printing process involves moving a blade or squeegee across a top surface of the stencil 400 to fill the openings 401 and 402 while removing excess material from the top surface of the stencil 400. An effect of this procedure is that the upper surface 104a of the epoxy spacers 104 on the side of the openings 401 and 402 where the squeegee or blade completed its transit of the openings 401 and 402 experiences a non-planar artifact 104b, colloquially known as a “dog's ear.” The height by which the non-planar artifact extends above the otherwise planar upper surface 104a of the epoxy spacers 104 can be greater than 20 μm, a height which would be sufficient to cause reliability issues with, or even damage to, a semiconductor device attached to the upper surface 104a of the epoxy spacer 104.

FIG. 6 illustrates the structure following the removal of the three-dimensional screen-printing stencil 400. In some embodiments of the present disclosure, the epoxy spacers 104 can be partially cured to a B-stage prior to, following, or concurrently with the removal of the stencil. Partially curing the epoxy spacers 104 can provide them with sufficient rigidity to largely retain their shape through subsequent manufacturing steps, while deferring completely curing the material until after planarization and final z-height adjustments have been made, as is set forth in greater detail below.

Because the non-planar artifacts 104b can cause mechanical stresses to structures that are stacked over them, one aspect of the present technology can provide a cost-effective solution to removing or ameliorating these non-planar artifacts 104b through a gang-pressing operation. This operation is shown schematically in FIG. 7, in which the substrate 101 on which the epoxy spacers 104 are formed is pressed between a gang-pressing tool 702 and a chuck table 701 to simultaneously planarize the upper surfaces 104a of multiple epoxy spacers 104 at a predetermined z-height. The partially-cured state of the epoxy spacers 104 permits a high level of z-height control to be obtained with a pressure-feedback system. During or following the pressing operation, the epoxy spacers 104 can be further heated to complete the cross-linking and fully cure the material thereof. According to one aspect of the present disclosure, the chuck table 701, the gang-pressing tool 702, or both, can be heated to provide thermal energy to the epoxy spacers 104 to perform this curing.

The gang-pressing tool 702 can have a planar lower surface that is large enough to simultaneously compresses multiple epoxy spacers 104 to their final height, a process which substantially planarizes the non-planar artifacts 104b introduced by the screen-printing process. When the epoxy spacers 104 are formed on multiple devices simultaneously (e.g., when the substrate 101 is in wafer, panel, or strip form prior to subsequent singulation), the gang-pressing operation can use a pressing surface large enough to planarize every epoxy spacer on the wafer, panel, or strip simultaneously, providing significant cost and throughput advantages. The pressing operation is capable of rendering the upper surfaces 104a of the epoxy spacers “substantially planar”—by which is meant that the non-planar artifacts 104b that extend above the otherwise planar upper surface 104a of each epoxy spacer 104 can be reduced in height to below 10 μm, below 5 μm, below 2 μm, or even below 1 μm. This level of co-planarity can permit the stacking of larger structures over the epoxy spacers 104 without risking damage or alignment issues caused by the protrusion of the non-planar artifacts 104b.

In some embodiments, the gang pressing tool 702 can have a transparent bottom surface (e.g., a glass panel), so that during or following the compression operation (e.g., while the gang pressing tool 702 continues to apply a compressive force at a predetermined level of pressure to obtain the desired z-height, or after the desired z-height has been achieved), the epoxy spacers 104 can be exposed to a UV illumination source to complete the cross-linking and fully cure the material thereof. Fully curing the epoxy spacer 104 while it is still constrained to the desired z-height can help to ensure that the co-planarity of the upper surface 104a of the epoxy spacer 104 and of the upper surface of the first semiconductor device 102a is not compromised by a change in shape of the epoxy spacer 104 after removal of the gang pressing tool 702, as might occur if the cross-linking of the epoxy material was not complete before the structure was mechanically disturbed (e.g., by the forces associated with removing a transparent release film, such as a film of polymethyl methacrylate (PMMA), disposed between the glass panel and the upper surfaces of the epoxy spacers 104 and the first semiconductor device 102a).

In some embodiments, the excess epoxy material that previously formed the non-planar artifacts 104b may be displaced by the gang-pressing operation to form non-planar artifacts 104c on the sidewalls 104d of the epoxy spacers 104 proximate the upper surfaces 104a thereof (i.e., near the upper corner between the upper surface 104a and the sidewall 104d), as may be more easily seen in FIG. 8, which illustrates the structure following the removal of the heated chuck table 701 and the gang-pressing tool 702. Depending upon the size of the original non-planar artifact 104b on the upper surface 104a, a displaced non-planar artifact 104c on the sidewall 104d of the epoxy spacer 104 may extend from the otherwise planar surface of the sidewall 104d by more than 5 μm, more than 10 μm, or even more than 20 μm. These non-planar artifacts 104c on the sidewalls 104d of the epoxy spacers 104 do not, however, have a negative impact on a subsequent stacking operation over the upper surfaces 104a of the epoxy spacers due to their location on the sidewalls 104d.

Turning to FIG. 9, the structure is shown following the attachment (e.g., via a die-attach film or other adhesive) of the second semiconductor dies 103 over the epoxy spacers 104 and the first semiconductor die 102. As can be seen with reference to FIG. 9, the substantially planar upper surfaces of the epoxy spacers 104 provide a supportive structure for carrying the delicate second semiconductor dies 103 over the first semiconductor die 102, and any non-planar artifact 104c of the planarization of the “dog's ears” are proximate an upper edge of one or more of the sidewalls 104d of the epoxy spacers 104. Following the formation of an encapsulant material over the structure, such as encapsulant material 105 illustrated in FIG. 1, the formation of the assembly 100 illustrated in FIG. 1 may be largely complete. In this regard, singulation of the assembly 100 from a wafer, panel, or strip, the attachment of solder balls to the external contacts of the substrate, and other subsequent processing and testing steps may follow, but are omitted from the illustration and description in the interest of clarity.

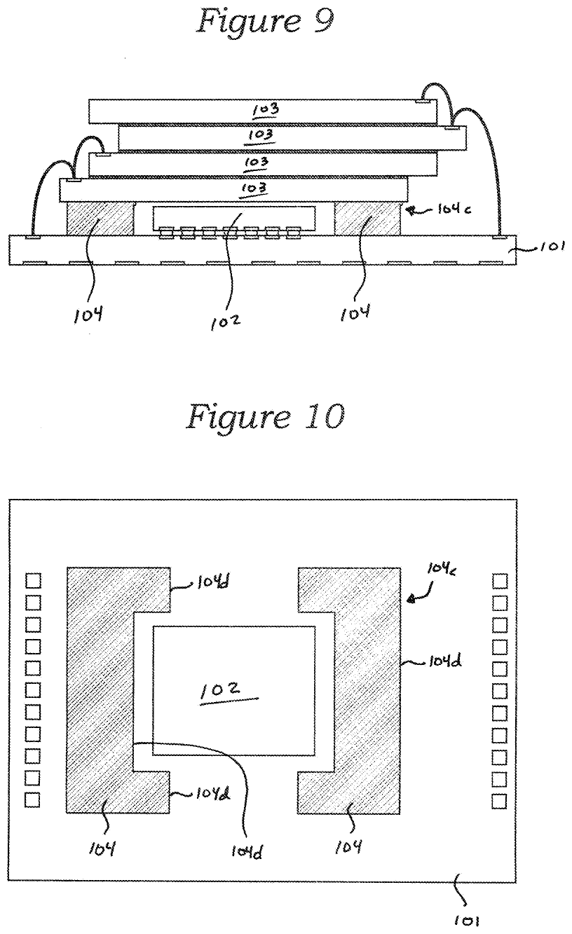

According to one aspect of the present technology, an advantage of the screen-printing approach for forming epoxy spacers is the design freedom permitted by the arbitrary shapes in which the epoxy spacers can be formed. In this regard, unlike silicon spacers or other spacers formed by cutting (e.g., with a mechanical saw) shapes from a larger workpiece, the openings formed in a stencil need not be limited to convex polygons, but can rather have more complicated shapes including curved sidewalls, concave polygons, etc. One such arrangement of a semiconductor device assembly with concave polygonal epoxy spacers is illustrated in the simplified schematic partial overhead view of FIG. 10, which depicts a semiconductor device assembly in accordance with an embodiment of the present technology.

As can be seen with reference to FIG. 10, the partially complete assembly structure (similar to that illustrated in cross-section in FIG. 8) can be seen to include a first semiconductor device 102 coupled to the upper surface of a substrate 101, with two epoxy spacers 104 formed on opposing sides thereof. Each epoxy spacer 104 has a concave polygonal shape (i.e., includes one or more internal angles greater than 180°). This “c” shaped outline of the epoxy spacers 104 permit them to wrap partially around the first semiconductor device 102, to provide more support to a second semiconductor device stacked thereon. An effect of the screen-printing operation used to form the epoxy spacers, and the pressing operation used to planarize them, is that any non-planar artifacts 104c that have been displaced to the sidewalls 104d of the epoxy spacers will be on sidewalls facing the same outer surface of the substrate 101 (e.g., in the illustrated embodiment, in which the screen-printing squeegee or blade was translated from left to right, the non-planar artifacts 104c that remain are located on sidewalls 104d that face the right outer edge of the substrate 101).

Although in the foregoing example embodiment semiconductor device assemblies have been illustrated and described with two epoxy spacers on opposing sides of a semiconductor device attached directly to a substrate, in other embodiments semiconductor device assemblies can have different arrangements of spacers and semiconductor devices, mutatis mutandis. For example, in some embodiments, a semiconductor device assembly may have only a single epoxy spacer (e.g., surrounding a semiconductor device on three sides), three or more epoxy spacers, and/or more than one semiconductor device directly attached to a substrate. Further, although semiconductor device assemblies have been illustrated and described as including second semiconductor devices “bridged” over a first semiconductor device, in other semiconductor device assemblies a second semiconductor device may only partially overhang a first semiconductor device. Moreover, although the first semiconductor device has been illustrated and described as a semiconductor die, in other semiconductor device assemblies epoxy spacers can be used to support semiconductor devices that overhang or bridge other devices, such as passive resistors, capacitors, inductors, or combinations of passive and active devices.

In accordance with one aspect of the present disclosure, the semiconductor devices illustrated in the assemblies of FIGS. 1-10 can include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above can include logic dies (e.g., controller dies, processor dies, etc.), or a mix of logic and memory dies (e.g., a memory controller die and a memory die controlled thereby).

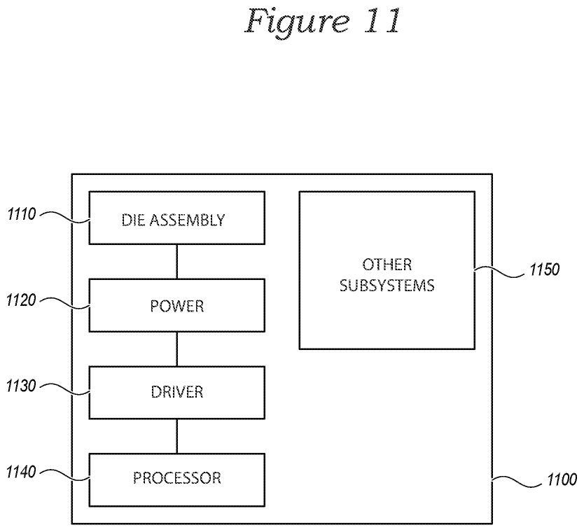

Any one of the semiconductor devices and semiconductor device assemblies described above with reference to FIGS. 1-10 can be incorporated into any of a myriad of larger and/or more complex systems, a representative example of which is system 1100 shown schematically in FIG. 11. The system 1100 can include a semiconductor device assembly (e.g., or a discrete semiconductor device) 1102, a power source 1104, a driver 1106, a processor 1108, and/or other subsystems or components 1110. The semiconductor device assembly 1102 can include features generally similar to those of the semiconductor devices described above with reference to FIGS. 1-10. The resulting system 1100 can perform any of a wide variety of functions, such as memory storage, data processing, and/or other suitable functions. Accordingly, representative systems 1100 can include, without limitation, hand-held devices (e.g., mobile phones, tablets, digital readers, and digital audio players), computers, vehicles, appliances and other products. Components of the system 1100 may be housed in a single unit or distributed over multiple, interconnected units (e.g., through a communications network). The components of the system 1100 can also include remote devices and any of a wide variety of computer readable media.

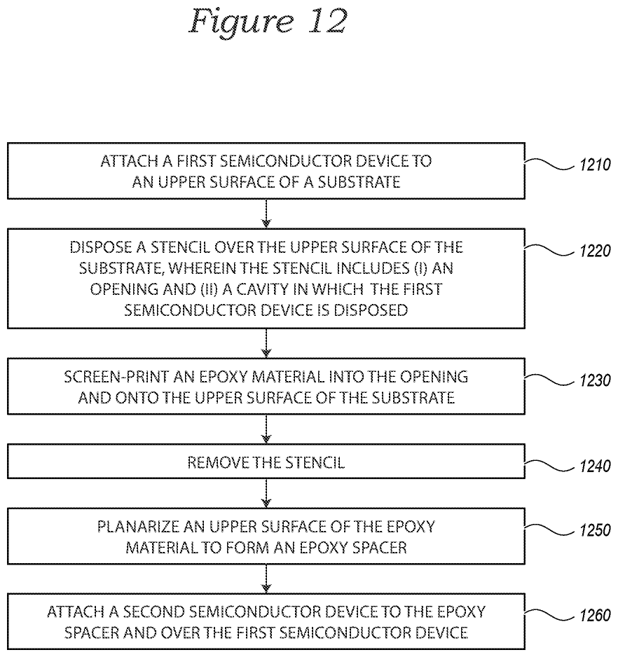

FIG. 12 is a flow chart illustrating a method of making a semiconductor device assembly. The method includes attaching a first semiconductor device to an upper surface of a substrate (box 1210) and disposing a stencil over the upper surface of the substrate, wherein the stencil includes an opening and a cavity in which the first semiconductor device is disposed (box 1220). The method further includes screen-printing an epoxy material into the opening and onto the upper surface of the substrate (box 1230), removing the stencil (box 1240), and planarizing an upper surface of the epoxy material to form an epoxy spacer (box 1250). The method can further include attaching a second semiconductor device to the epoxy spacer and over the first semiconductor device (1260).

Although in the foregoing example embodiment the formation of semiconductor device assemblies have been illustrated and described as involving a screen-printing step with a 3D stencil to permit screen printing on a substrate to which devices (e.g., semiconductor dies, passive circuit elements, etc.) have already been attached, in other embodiments of the present technology a die-attach and/or a passive-element-attach step may be performed after a screen-printing operation (e.g., potentially obviating the 3D stencil). In yet other embodiments, some devices may already be attached to the substrate before screen printing the spacers, and others may be attached afterwards.

Specific details of several embodiments of semiconductor devices, and associated systems and methods, are described above. According to one aspect of the present disclosure, suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method of making a semiconductor device assembly, comprising:
attaching a first semiconductor device to an upper surface of a substrate;
disposing a stencil over the upper surface of the substrate, wherein the stencil includes (i) an opening and (ii) a cavity in which the first semiconductor device is disposed;
screen-printing an epoxy material into the opening and onto the upper surface of the substrate;
removing the stencil; and
planarizing an upper surface of the epoxy material to form an epoxy spacer.

2. The method of claim 1, wherein the cavity extends only partially through the stencil from a lower surface thereof.

3. The method of claim 1, wherein planarizing the upper surface of the epoxy material comprises pressing a planar surface of a pressing tool into the upper surface of the epoxy material.

4. The method of claim 1, wherein the opening has a concave polygonal shape.

5. The method of claim 1, further comprising applying heat to partially cure the epoxy material before planarizing the upper surface of the epoxy material.

6. The method of claim 1, further comprising applying heat to fully cure the epoxy spacer.

7. The method of claim 1, further comprising attaching a second semiconductor device to the epoxy spacer and over the first semiconductor device.

8. A method of making a plurality of semiconductor device assemblies, comprising:
attaching a plurality of first semiconductor devices to an upper surface of a panel;
disposing a stencil over the upper surface of the panel, wherein the stencil includes (i) a plurality of openings and (ii) a plurality of cavities in which the plurality of first semiconductor devices are disposed;
screen-printing an epoxy material into the plurality of openings and onto the upper surface of the panel;
removing the stencil; and
planarizing upper surfaces of the epoxy material to form a plurality of epoxy spacers.

9. The method of claim 8, wherein the cavities extend only partially through the stencil from a lower surface thereof.

10. The method of claim 8, wherein planarizing the upper surfaces of the epoxy material comprises pressing a planar surface of a gang-pressing tool into the upper surfaces of the epoxy material.

11. The method of claim 10, wherein planarizing the upper surfaces of the epoxy material further comprises applying heat to a lower surface of the panel opposite the upper surface.

12. The method of claim 8, further comprising applying heat to partially cure the epoxy material before planarizing the upper surfaces of the epoxy material.

13. The method of claim 8, further comprising applying heat to fully cure the plurality of epoxy spacers.

14. The method of claim 8, further comprising attaching a plurality of second semiconductor devices to the plurality of epoxy spacers and over the plurality of first semiconductor devices.

15. The method of claim 8, further comprising singulating the panel into a plurality of substrates, each including a corresponding first semiconductor device and at least one of the plurality of epoxy spacers.

16. A semiconductor device assembly, comprising:
a substrate;
a first semiconductor die coupled to a surface of the substrate;
an epoxy spacer coupled directly to the surface of the substrate, the epoxy spacer having a substantially planar upper surface and a sidewall with a non-planar artifact proximate the upper surface; and
a second semiconductor die carried by the epoxy spacer over the first semiconductor die.

17. The semiconductor device assembly of claim 16, wherein the epoxy spacer has a concave polygonal shape.

18. The semiconductor device assembly of claim 16, wherein:
the epoxy spacer is a first epoxy spacer,
the semiconductor device assembly further comprises a second epoxy spacer coupled directly to the surface of the substrate, the second epoxy spacer having a substantially planar upper surface co-planar with the upper surface of the first epoxy spacer, and
the second semiconductor die is carried by the first epoxy spacer and the second epoxy spacer.

19. The semiconductor device assembly of claim 18, wherein the first and second epoxy spacers are on opposing sides of the first semiconductor die.

20. The semiconductor device assembly of claim 18, wherein a bottom surface of the second semiconductor die is vertically spaced apart from an upper surface of the first semiconductor die.
